(19) United States
(12) Patent Application Publication
(10) Pub. No.: US 2005/0166958 A1
(43) Pub. Date: Aug. 4, 2005

(54) Dye-sensitized solar cell having enlarged wavelength range for light absorption and method of fabricating same

(76) Inventors: Joung-Won Park, Suwon-si (KR); Ji-Won Lee, Suwon-si (KR); Wha-Sup Lee, Suwon-si (KR); Kwang-Soon Ahn, Suwon-si (KR); Jae-Man Choi, Suwon-si (KR); Byong-Cheol Shin, Suwon-si (KR)

Correspondence Address: CHRISTIE, PARKER & HALE, LLP, PO BOX 7068, PASADENA, CA, 91109-7068, US

(21) Appl. No.: 11/046,511

(22) Filed: Jan. 28, 2005

(30) Foreign Application Priority Data
Feb. 3, 2004 (KR) 10-2004-0006930

(51) Int. Cl. H01L 31/00

(52) U.S. Cl. 136/263; 136/256

(57) ABSTRACT

A dye-sensitized solar cell with an enlarged effective wavelength range for light energy absorption and enhanced photoelectric conversion efficiency, and a method of fabricating such a solar cell are disclosed. The dye-sensitized solar cell comprises a first electrode comprising a light transmission material, and a second electrode facing the first electrode. A porous layer is formed on the first electrode, and a composite dye is absorbed to the porous layer. The composite dye comprises two or more dye materials. An electrolyte is impregnated between the first and second electrodes.

### CROSS-REFERENCE TO RELATED APPLICATION

This application claims priority to and the benefit of Korean Patent Application No. 10-2004-0006930 filed on Feb. 3, 2004 in the Korean Intellectual Property Office, the entire disclosure of which is incorporated herein by reference.

### FIELD OF THE INVENTION

The present invention relates to a dye-sensitized solar cell and a method of fabricating the same, and in particular, to a dye-sensitized solar cell and a method of fabricating a dye-sensitized solar cell comprising a composite dye.

### BACKGROUND OF THE INVENTION

A dye-sensitized solar cell is a cell for converting solar energy into electric energy based on photosynthesis. Dye-sensitized solar cells involve relatively easy processing steps and low production cost, as compared to conventional silicon solar cells. As dye-sensitized solar cells are formed with transparent electrodes, they may be used in making windows for outer walls of buildings, or in making glass houses. Michael Gratzel of Ecole Polytechnique Federale de Lausanne (EPFL, Switzerland) conducted a prominent study concerning dye-sensitized solar cells in 1991.

A typical dye-sensitized solar cell has a first electrode with a dye-absorbed metallic oxide film, and a second electrode facing the first electrode and separated from the first electrode by a predetermined distance.

Dye-sensitized solar cells typically have low photoelectric conversion efficiency, and are therefore limited in their practical usage. To solve this problem, the sunlight absorption of the solar cell or the dye absorption thereof should be increased.

For this purpose, it has been conventionally proposed that the electrode reflectivity be heightened, that light scattering particles be used to increase sunlight absorption, or that the metallic oxide particles be dimensioned up to the nanometer level. However, such techniques are limited in enhancing the photoelectric conversion efficiency of the solar cell, and new technologies are needed to enhance the energy efficiency of the cell.

### SUMMARY OF THE INVENTION

In one embodiment of the present invention a dye-sensitized solar cell is provided which enlarges the effective wavelength range for light absorption to thereby enhance the photoelectric conversion efficiency of the solar cell.

Enlarged effective wavelength range for light absorption and enhanced photoelectric conversion efficiency is realized in a dye-sensitized solar cell with the following features.

According to one embodiment of the present invention, the dye-sensitized solar cell includes a first electrode comprising a light transmission material, and a second electrode facing the first electrode. A porous layer is formed on the first electrode, and a composite dye is absorbed to the porous layer, the composite dye comprising two or more dye materials. An electrolyte is impregnated between the first and second electrodes.

The composite dye may comprise Ru(2,2′:6′-2″-terpyridine-4,4′,4″-tricarboxylic acid)(NCS)₃.

Ru(2,2′:6′-2″-terpyridine-4,4′,4″-tricarboxylic acid)(NCS)₃ may be present in the composite dye in an amount ranging from about 10 to about 80 mol %.

And, the composite dye may further comprises Ru(4,4′-dicarboxy-2,2′-bipyridine)₂(CN)₂.

The porous layer comprises metallic oxide particles with a mean particle diameter of 100 nm or less. The mean particle diameter of the metallic oxide particles preferably ranges from about 10 to about 40 nm.

The porous layer further comprises conductive particles or light scattering particles. The light scattering particles are preferably formed from the same material as the metallic oxide particles of the porous layer, and have a mean particle diameter of 100 nm or more.

The first electrode comprises: a transparent substrate formed from a material selected from the group consisting of polyethylene terephthalate (PET), polyethylene naphthalate (PEN), polycarbonate (PC), polypropylene (PP), polyimide (PI) and triacetate cellulose (TAC); and a conductive film coated on the substrate selected from the group consisting of indium tin oxide (ITO), fluorine tin oxide (FTO), ZnO—Ga₂O₃, ZnO—Al₂O₃ and SnO₂—Sb₂O₃.

The second electrode comprises: a transparent substrate formed from a material selected from the group consisting of polyethylene terephthalate (PET), polyethylene naphthalate (PEN), polycarbonate (PC), polypropylene (PP), polyimide (PI) and triacetate cellulose (TAC); a first conductive film coated on the substrate selected from the group consisting of indium tin oxide (ITO), fluorine tin oxide (FTO), ZnO—Ga₂O₃, ZnO—Al₂O₃ and SnO₂—Sb₂O₃; and a second conductive film coated on the first conductive film, the second conductive film being selected from the group consisting of Pt and precious metals.

In an alternative embodiment of the present invention, the dye-sensitized solar cell comprises a first electrode comprising a light transmission material, and a second electrode facing the first electrode. A porous layer is formed on the first electrode. A composite dye comprising two or more dye materials is absorbed on the porous layer. The first and second dye materials respectively comprise Ru complexes having different ligands. An electrolyte is impregnated between the first and the second electrodes.

One method of fabricating a dye-sensitized solar cell comprises preparing first and second electrodes comprising light transmission materials. A porous layer is then formed on a surface of the first electrode. A composite dye comprising two or more dye materials is prepared and absorbed into the porous layer. The first and second electrodes are arranged such that the porous layer of the first electrode faces the second electrode. An electrolyte is then impregnated between the first and second electrodes, and sealed.

The composite dye may be prepared by adding Ru(2,2′:6′-2″-terpyridine-4,4′,4″-tricarboxylic acid)(NCS)₃ to a dye precursor. Ru(2,2′:6′-2″-terpyridine-4,4′,4″-tricarboxylic acid)(NCS)₃ is present in the composite dye in an amount ranging from about 10 to about 80 mol %.

The composite dye is prepared by dissolving Ru(2,2′:6′-2″-terpyridine-4,4′,4″-tricarboxylic acid)(NCS)₃ in alcohol to a concentration of 0.1˜5 mM, and adding another dye material to the alcohol.

And, the composite dye further comprises Ru(4,4′-dicarboxy-2,2′-bipyridine)₂(CN)₂.

According to one embodiment of the dye-sensitized solar cell of the present invention, the composite dye comprises two or more dye materials having different wavelength regions, thereby enlarging the effective wavelength range for light energy absorption. Consequently, the energy efficiency of the dye-sensitized solar cell is enhanced.

### BRIEF DESCRIPTION OF THE DRAWINGS

The above and other advantages of the present invention will become more apparent by describing preferred embodiments thereof in detail with reference to the accompanying drawings in which:

FIG. 1 is a representational cross sectional view of a dye-sensitized solar cell according to an embodiment of the present invention;

FIG. 2 is a graphical comparison of the relationship between the degree of light absorption and the wavelength of a dye-sensitized solar cell according to the prior art with that of a dye-sensitized solar cell according to an embodiment of the present invention;

FIG. 3 is a graphical comparison of the relationship between the voltage and current density of a dye-sensitized solar cell according to Comparative Examples 1 and 2, and Example 1; and

FIG. 4 is a graphical comparison of the incident photon-to-current conversion efficiency (IPCE) of dye-sensitized solar cells according to Comparative Examples 1 and 2, and Example 1.

### DETAILED DESCRIPTION

The present invention will be described more fully hereinafter with reference to the accompanying drawings, in which alternative embodiments of the invention are shown.

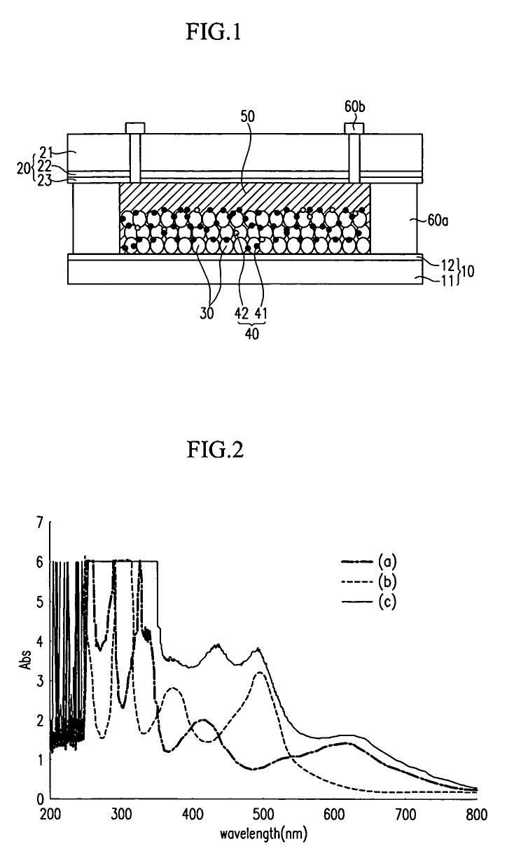

FIG. 1 is a representational cross sectional view of a dye-sensitized solar cell according to an embodiment of the present invention.

As shown in FIG. 1, the dye-sensitized solar cell comprises a first electrode 10 comprising a light transmission material, and a second electrode 20 facing the first electrode 10 and separated from the first electrode 10 by a predetermined distance. A porous layer 30 is formed on the surface of the first electrode 10, and faces the second electrode 20. A composite dye 40 is absorbed to the porous layer 30. The space between the first and the second electrodes 10 and 20 is filled with an electrolyte 50.

The first electrode 10 comprises a transparent substrate 11, and a conductive film 12 coated on the substrate 11. The substrate 11 is selected from the group consisting of polyethylene terephthalate (“PET”), polyethylene naphthalate (“PEN”), polycarbonate (“PC”), polypropylene (“PP”), polyimide (“PI”), triacetate cellulose (“TAC”), and combinations thereof. The conductive film 12 is selected from the group consisting of indium tin oxide (“ITO”), fluorine tin oxide (“FTO”), ZnO—Ga₂O₃, ZnO—Al₂O₃, SnO₂—Sb₂O₃, and combinations thereof.

The porous layer 30 is formed on the surface of the first electrode 10 and faces the second electrode 20. The porous layer 30 contains metallic oxide particles having nanometer-level mean particle diameters. Nonlimiting examples of particles suitable for use in the porous layer are TiO₂ particles. The metallic oxide particles of the porous layer 30 preferably have equal particle diameters such that the porous layer 30 can bear a high porosity and an optimal surface roughness.

The metallic oxide particles of the porous layer 30 have mean particle diameters of 100 nm or less, preferably 10˜40 nm. Based on the particle diameters of a TiO₂-based porous layer, when the mean particle diameter of the metallic oxide particles is less than 10 nm, the adhesive force is too weak to form a stable porous layer. When the mean particle diameter of the metallic oxide particles exceeds 40 nm, the surface area of the dye-absorbed porous layer 30 is reduced, thereby reducing photoelectric conversion efficiency.

The porous layer 30 is formed by coating an oxide paste onto the inner surface of the first electrode 10, and heat-treating the paste.

A doctor blade or screen-printing technique is used to coat the paste onto the first electrode 10. Spin coating or spraying may be used to form the porous layer 30 on the transparent material of the first electrode 10. A common wet coating technique can also be used. The physical properties of the paste differ depending on the coating technique used.

When a binder is added to the paste, the paste is heat-treated at 450-600° C. for 30 minutes. In the absence of such a binder, the paste can be heat-treated at a temperature of 200° C. or cooler.

The porous layer 30 further comprises a polymer to maintain its porosity. The polymer is preferably one which will not leave any organic material after heat treatment. Nonlimiting examples of suitable polymers include polyethylene glycol (“PEG”), polyethylene oxide (“PEO”), polyvinyl alcohol (“PVA”), and polyvinyl pyrrolidone (“PVP”). Polymer selection may vary depending on the coating technique used. A polymer with the proper molecular weight based on the coating technique is selected and then added to the porous layer 30. When the polymer is added to the porous layer 30, the porosity of the porous layer is increased, and the diffusivity and viscosity of the porous layer 30 are also increased, thereby enhancing film formation and adhesive force of the film to the substrate.

And, the porous layer 30 further comprises conductive particles or light scattering particles. The conductive particles facilitate easy migration of electrons, and comprise ITO. The light scattering particles enlarge the optical path length and enhance photoelectric conversion efficiency. The light scattering particles comprise the same material as the metallic oxide of the porous layer, and have mean particle diameters of 100 nm or more.

A composite dye 40, comprising two or more dye materials, is absorbed to the metallic oxide particles of the porous layer 30. The dye 40 comprises two or more dye materials having different wavelength regions for absorption in order to enlarge the effective wavelength range for light absorption. The dye materials comprise a metal complex selected from the group consisting of Al, Pt, Pd, Eu, Pb, Ir and Ru complexes, and combinations thereof. The dye materials are capable of absorbing visible rays. Ruthenium (Ru) is an element in the platinum group which is capable of forming a number of organic metal complex compounds.

Dyes improving absorption of long wavelength parts of visible rays to enhance the energy efficiency and new type dyes capable of easily making the electron emission are suitable for use in the solar cells of present invention. And, dyes for improving the reactor of the dyes may be used in the solar cells of the present invention to prevent recombination of electrons and holes.

Organic pigments may also be used as components of the composite dye used in the dye-sensitized solar cells of the present invention. The organic pigment is selected from the group consisting of coumarin, porphyrin, xanthene, riboflavin, triphenylmethane, and combinations thereof. The organic pigment may be used by itself, or in combination with the Ru complex. The organic pigment is cost effective, abundant and readily available. Furthermore, the organic pigment improves absorption of the long-wavelength visible ray parts, and enhances cell energy efficiency.

In order to naturally absorb the dye 40 to the porous layer 30, the first electrode 10 coated with the porous layer 30 is dipped in an alcoholic solution containing the dye materials for about 12 hours.

As shown in FIG. 1, the composite dye 40 is formed with a mixture of a first dye material 41 and a second dye material 42. However, the composite dye 40 is not limited thereto, and may contain other materials.

The first and second dye materials 41 and 42, respectively, may be formed with Ru complexes having different ligands. In one embodiment, the first dye material 41 comprises Ru(2,2′:6′-2″-terpyridine-4,4′,4″-tricarboxylic acid)(NCS)₃. To enhance long wavelength energy absorption, the first dye material 41 is present in the composite dye 40 in an amount ranging from about 10 to about 80 mol %.

The second dye material 42 may comprise Ru(4,4′-dicarboxy-2,2′-bipyridine)₂(CN)₂.

The second electrode 20 faces the first electrode 10, and has a transparent substrate 21 and a first conductive film 22 coated on the substrate 21. The second electrode 20 may further comprise a second conductive film 23 coated on the first conductive film 22. The substrate 21 comprises a material selected from the group consisting of PET, PEN, PC, PP, PI and TAC, and the first conductive film 22 comprises a material selected from the group consisting of ITO, FTO, ZnO—Ga₂O₃, ZnO—Al₂O₃ and SnO₂—Sb₂O₃. The second conductive film 23 comprises a material selected from the group consisting of Pt and precious metals.

To make the second conductive film 23 comprising Pt, a solution that H₂PtCl₆ is dissolved in an organic solvent selected from the group consisting of MeOH, EtOH and IPA(isopropyl alcohol), is wet-coated onto the first conductive film 22 by spin coating, dip coating or flow coating, and heat-treated at a temperature of 400° C. or higher under an air or oxygen atmosphere. Alternatively, physical vapor deposition (PVD) such as electrolyte plating, sputtering or electron beam deposition may be used.

The electrolyte 50 is impregnated between the first and second electrodes 10 and 20, and uniformly diffused into the inside of the porous layer 30. The electrolyte 50 comprises iodide and triiodide, receives electrons from the second electrode 20 and transfers them to the dye 40 through oxidation and reduction. The voltage of the solar cell is determined by the energy level of the dye and the difference between the levels of oxidation and reduction of the electrolyte 50.

In one embodiment of a solar cell according to the present invention, the first and the second electrodes 10 and 20, are attached to each other by an adhesive 60a. The second electrode 20 is penetrated to form a small hole. A solution for forming the electrolyte 50 is injected into the space between the two electrodes via the hole, which is then externally sealed using an adhesive 60b.

The adhesives 60a and 60b may each comprise a thermoplastic polymer film, such as SURLYN™. The thermoplastic polymer film is disposed between the two electrodes, and thermally pressed. An epoxy resin or ultraviolet (UV) hardening agent may be used to form the adhesives 60a and 60b, in which case the adhesive is hardened after heat treatment or UV treatment.

When sunlight is incident upon the solar cell, the photons are first absorbed into the dye molecules, and the dye molecules are excited from the ground state to the excited state through electron transfer to make electron-hole pairs. The excited electrons are introduced into the conduction band of the transition metal oxide forming the porous layer, transported to the external circuit via the first electrode, and the electrons then migrate to the counter electrode. The iodide (I⁻) within the electrolyte is oxidized to triiodide (I₃⁻), thereby reducing the oxidized dye. The triiodide (I₃⁻) reacts with the electrons that migrated to the second electrode, and is reduced to iodide (I⁻). Thus, the migration of electrons operates the solar cell.

In one embodiment of a solar cell according to the present invention, the composite dye comprises a mixture of two or more dye materials having different wavelength ranges, thereby increasing the long-wavelength energy absorption of the visible rays. This will be explained with reference to FIG. 2.

FIG. 2 compares the light absorption degree (Abs) as a function of wavelength of a dye-sensitized solar cell according to the prior art to that of a dye-sensitized solar cell according to one embodiment of the present invention. FIG. 2 graphs: (a) a dye-sensitized solar cell using a single dye comprising Ru(2,2′:6′-2″-terpyridine-4,4′,4″-tricarboxylic acid)(NCS)₃, (b) a dye-sensitized solar cell using a single dye comprising Ru(4,4′-dicarboxy-2,2′-bipyridine)₂(CN)₂, and (c) a dye-sensitized solar cell using a composite dye comprising a mixture of Ru(2,2′:6′-2″-terpyridine-4,4′,4″-tricarboxylic acid)(NCS)₃ and Ru(4,4′-dicarboxy-2,2′-bipyridine) ₂ (CN)₂.

As shown in FIG. 2, the wavelength range for light absorption of the solar cell using the composite dye, shown as line (c), is larger than that of the solar cells using the single dyes Ru(2,2′:6′-2″-terpyridine-4,4′,4″-tricarboxylic acid)(NCS)₃ and Ru(4,4′-dicarboxy-2,2′-bipyridine)₂(CN)₂, shown as lines (a) and (b), respectively.

During the first step of operating a dye-sensitized solar cell, the dye molecules generate photo-charges from light energy. Accordingly, to enhance the energy efficiency of the dye-sensitized solar cell, the effective light energy absorption of the dye molecules should be increased or the effective wavelength range for light absorption should be enlarged.

In one embodiment of a solar cell according to the present invention, the effective wavelength range for light energy absorption is enlarged by using a composite dye comprising two or more dye materials have different wavelength regions for absorption.

In a method of fabricating a dye-sensitized solar cell according to the present invention, first and second electrodes comprising light transmission materials are prepared, and a porous layer is formed on a surface of the first electrode. Two or more dye materials are mixed to form a composite dye, and the composite dye is absorbed to the porous layer. Thereafter, the first and second electrodes are arranged such that the porous layer of the first electrode faces the second electrode. An electrolyte is injected between the first and second electrodes and sealed, thereby fabricating a dye-sensitized solar cell.

According to one method of preparing the composite dye, Ru(2,2′:6′-2″-terpyridine-4,4′,4″-tricarboxylic acid)(NCS)₃ is dissolved in a solvent, such as alcohol, and another dye material, such as Ru(4,4′-dicarboxy-2,2′-bipyridine)₂(CN)₂, is added thereto.

It is preferable that Ru(2,2′:6′-2″-terpyridine-4,4′,4″-tricarboxylic acid)(NCS)₃ is dissolved in an alcohol to a concentration ranging from about 0.1 to about 5 mM, and another dye material is added thereto.

In this case, Ru(2,2′:6′-2″-terpyridine-4,4′,4″-tricarboxylic acid)(NCS)₃ is present in the composite dye in an amount ranging from about 10 to about 80 mol %.

One example of the present invention will now be explained. However, the example is merely illustrative and does not limit the scope of the present invention.

### EXAMPLE 1

An ITO-based film was coated on a transparent substrate to form a first electrode. A dispersed solution of TiO₂ particles having a mean particle diameter of 5˜15 nm was coated onto a 1 cm² ITO-based film using a doctor blade technique, and fired at 450° C. for 30 minutes to form a porous layer with a thickness of about 3 μm.

Thereafter, 0.3 mM Ru(4,4′-dicarboxy-2,2′-bipyridine)₂(CN)₂ and 0.45 mM Ru(2,2′:6′-2″-terpyridine-4,4′,4″-tricarboxylic acid)(NCS)₃ were dissolved in ethanol to form a dye solution, and the first electrode with the porous layer was dipped in the dye solution at 80° C. for 12 hours or more such that the dye absorbed to the porous layer. The dye-absorbed porous titanium oxide film was then cleaned using ethanol, and dried at ambient temperature.

ITO and Pt-based films were coated on a transparent substrate to form a second electrode. A 0.75 mm diameter hole for injecting an electrolyte was formed at the second electrode using a drill.

The Pt-based film of the second electrode was positioned facing the porous layer on the first electrode, and a thermoplastic polymer film with a thickness of 60 μm was placed between the first and second electrodes. The first and second electrodes were pressed at 100° C. for nine seconds to attach them to each other. An electrolyte was injected between the two electrodes through the hole formed at the second electrode, and the hole was sealed using a cover glass and thermoplastic polymer film, thereby making a dye-sensitized solar cell. The electrolyte was prepared by dissolving 0.62 M 1,2-dimethyl-3-hexylimidazolium iodide, 0.5 M 2-aminopyrimidine, 0.1 M lithium iodide (LiI) and 0.05 M I₂ in an acetonitrile solvent.

### COMPARATIVE EXAMPLE 1

An ITO-based film was coated on a transparent substrate to form a first electrode. A dispersed solution of TiO₂ particles having a mean particle diameter of 5-15 nm was coated onto a 1 cm² ITO-based film using a doctor blade technique, and fired at 450° C. for 30 minutes to thereby form a porous layer with a thickness of about 3 μm.

Thereafter, 0.45 mM Ru(2,2′:6′-2″-terpyridine-4,4′,4″-tricarboxylic acid)(NCS)₃ was dissolved in ethanol to form a dye solution, and the first electrode with the porous layer was dipped in the dye solution at 80° C. for 12 hours or more such that the dye was absorbed into the porous layer. The dye-absorbed porous titanium oxide film was then cleaned using ethanol, and dried at ambient temperature.

ITO and Pt-based films were coated on a transparent substrate to form a second electrode. A 0.75 mm diameter hole for injecting an electrolyte was formed at the second electrode using a drill.

The Pt-based film of the second electrode was positioned facing the porous layer of the first electrode, and a thermoplastic polymer film with a thickness of 60 μm was placed between the first and second electrodes. The first and second electrodes were pressed at 100° C. for nine seconds to attach them to each other. An electrolyte was injected between the two electrodes through the hole formed at the second electrode, and the hole was sealed using a cover glass and thermoplastic polymer film, thereby making a dye-sensitized solar cell. The electrolyte was prepared by dissolving 0.62 M 1,2-dimethyl-3-hexylimidazolium iodide, 0.5 M 2-aminopyrimidine, 0.1 M lithium iodide (LiI) and 0.05 M I₂ in an acetonitrile solvent.

### COMPARATIVE EXAMPLE 2

An ITO-based film was coated on a transparent substrate to form a first electrode. A dispersed solution of TiO₂ particles having a mean particle diameter of 5-15 nm was coated onto a 1 cm² ITO-based film using a doctor blade technique, and fired at 450° C. for 30 minutes to thereby form a porous layer with a thickness of about 3 μm.

Thereafter, 0.3 mM Ru(4,4′-dicarboxy-2,2′-bipyridine)₂(CN)₂ was dissolved in ethanol to form a dye solution, and the first electrode with the porous layer was dipped in the dye solution at 80° C. for 12 hours or more such that the dye was absorbed into the porous layer. The dye-absorbed porous titanium oxide film was then cleaned using ethanol, and dried at ambient temperature.

ITO and Pt-based films were coated on a transparent substrate to form a second electrode. A 0.75 mm diameter hole for injecting an electrolyte was formed at the second electrode using a drill.

The Pt-based film of the second electrode was positioned facing the porous layer of the first electrode, and a thermoplastic polymer film with a thickness of 60 μm was placed between the first and second electrodes. The first and second electrodes were pressed at 100° C. for nine seconds to attach them to each other. An electrolyte was injected between the two electrodes through the hole formed at the second electrode, and the hole was sealed using a cover glass and thermoplastic polymer film, thereby making a dye-sensitized solar cell. The electrolyte was prepared by dissolving 0.62 M 1,2-dimethyl-3-hexylimidazolium iodide, 0.5 M 2-aminopyrimidine, 0.1 M lithium iodide (LiI) and 0.05 M I₂ in an acetonitrile solvent.

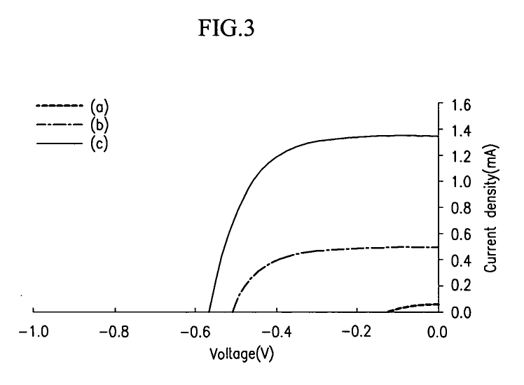

FIG. 3 illustrates the relationship between the voltage and current density of dye-sensitized solar cells prepared according to Comparative Examples 1 and 2, and Example 1. FIG. 3 graphs: (a) the voltage-current density curve of the dye-sensitized solar cell prepared according to Comparative Example 1, (b) the voltage-current density curve of the dye-sensitized solar cell prepared according to Comparative Example 2, and (c) the voltage-current density curve of the dye-sensitized solar cell prepared according to Example 1. Voltage and current density were measured using a standard Si cell with a light source of 100 mW/cm².

The energy efficiency, open circuit voltage, short circuit current, and fill factor (FF) of the dye-sensitized solar cells according to Example 1 and Comparative Examples 1 and 2 were determined from the corresponding voltage-current density curves.

The dye-sensitized solar cell according to Example 1 exhibited 0.48% energy efficiency, 0.567 V open circuit voltage, 1.34 mA/cm² short circuit current, and a 0.63 fill factor. By contrast, the dye-sensitized solar cell according to Comparative Example 1 exhibited 0.0002% energy efficiency, 0.093 V open circuit voltage, 0.01 mA/cm² short circuit current, and a 0.30 fill factor. The dye-sensitized solar cell according to Comparative Example 2 exhibited 0.16% energy efficiency, 0.505 V open circuit voltage, 0.49 mA/cm² short circuit current, and a 0.65 fill factor.

These results show that the dye-sensitized solar cell prepared according to Example 1 has higher energy efficiency than that of the dye-sensitized solar cells according to both Comparative Examples 1 and 2. Particularly, the open circuit voltage and short circuit current of the cell prepared according to Example 1 are higher than those of the cells prepared according to Comparative Examples 1 and 2.

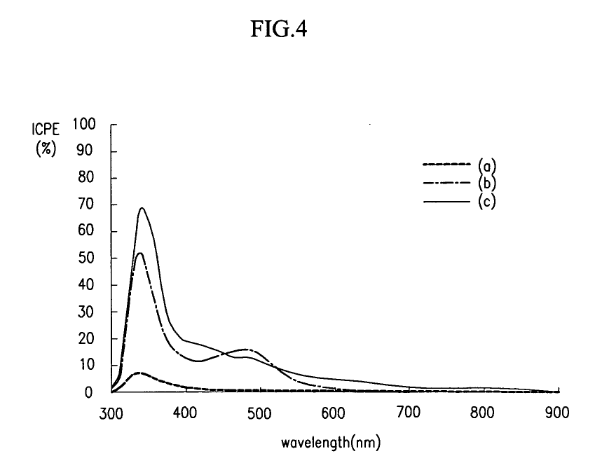

FIG. 4 illustrates the incident photon-to-current conversion efficiency (IPCE) of dye-sensitized solar cells prepared according to Comparative Examples 1 and 2, and Example 1.

FIG. 4 graphs: (a) the IPCE of a dye-sensitized solar cell prepared according to Comparative Example 1, (b) the IPCE of a dye-sensitized solar cell prepared according to Comparative Example 2, and (c) the IPCE of a dye-sensitized solar cell according to Example 1.

As shown in FIG. 4, the IPCE of the dye-sensitized solar cell prepared according to Example 1 (using a composite dye) is higher than that of the dye-sensitized solar cells prepared according to Comparative Examples 1 and 2 (using a single dye).

As described above, the effective wavelength range for light energy absorption of the dye-sensitized solar cell according to the present invention is enlarged by using a composite dye with two or more dye materials having different wavelength regions for absorption. Consequently, the energy efficiency of the dye-sensitized solar cell is enhanced.

Although preferred embodiments of the present invention have been described in detail hereinabove, it should be clearly understood that many variations and/or modifications of the basic inventive concept herein taught will be appreciated by those skilled in the art, and fall within the spirit and scope of the present invention, as defined in the appended claims.

1. A dye-sensitized solar cell comprising:
a first electrode comprising a light transmission material;
a porous layer formed on a surface of the first electrode;
a composite dye absorbed to the porous layer, the composite dye comprising two or more dye materials;
a second electrode facing the porous layer on the first electrode; and
an electrolyte impregnated between the first and second electrodes.

2. The dye-sensitized solar cell of claim 1, wherein one of the dye materials of the composite dye comprises Ru(2,2′:6′-2″-terpyridine-4,4′,4″-tricarboxylic acid)(NCS)₃.

3. The dye-sensitized solar cell of claim 2, wherein Ru(2,2′:6′-2″-terpyridine-4,4′,4″-tricarboxylic acid)(NCS)₃ is present in the composite dye in an amount ranging from about 10 to about 80 mol %.

4. The dye-sensitized solar cell of claim 1, wherein the composite dye comprises Ru(2,2′:6′-2″-terpyridine-4,4′,4″-tricarboxylic acid)(NCS)₃ and Ru(4,4′-dicarboxy-2,2′-bipyridine)₂(CN)₂.

5. The dye-sensitized solar cell of claim 1, wherein the porous layer comprises a plurality of metallic oxide particles having a mean particle diameter of 100 nm or less.

6. The dye-sensitized solar cell of claim 5, wherein the mean particle diameter of the metallic oxide particles is 10˜40 nm.

7. The dye-sensitized solar cell of claim 5, wherein the porous layer further comprises a plurality of particles selected from the group consisting of conductive particles and light scattering particles.

8. The dye-sensitized solar cell of claim 5, wherein the porous layer further comprises a plurality of light scattering particles, and the light scattering particles comprise the same material as the metallic oxide particles of the porous layer, the light scattering particles having a mean particle diameter of 100 nm or more.

9. The dye-sensitized solar cell of claim 1, wherein the first electrode comprises: a transparent substrate selected from the group consisting of polyethylene terephthalate (PET), polyethylene naphthalate (PEN), polycarbonate (PC), polypropylene (PP), polyimide (PI) and triacetate cellulose (TAC); and a conductive film coated on the substrate, the conductive film selected from the group consisting of indium tin oxide (ITO), fluorine tin oxide (FTO), ZnO—Ga₂O₃, ZnO—Al₂O₃ and SnO₂—Sb₂O₃.

10. The dye-sensitized solar cell of claim 1, wherein the second electrode comprises: a transparent substrate selected from the group consisting of polyethylene terephthalate (PET), polyethylene naphthalate (PEN), polycarbonate (PC), polypropylene (PP), polyimide (PI) and triacetate cellulose (TAC); a first conductive film coated on the substrate, the first conductive film selected from the group consisting of indium tin oxide (ITO), fluorine tin oxide (FTO), ZnO—Ga₂O₃, ZnO—Al₂O₃ and SnO₂—Sb₂O₃; and a second conductive film coated on the first conductive film, the second conductive film selected from the group consisting of Pt and precious metals.

11. A dye-sensitized solar cell comprising:
a first electrode comprising a light transmission material;
a porous layer formed on a surface of the first electrode;
a composite dye absorbed to the porous layer, the composite dye comprising first and second dye materials, the first and second dye materials respectively comprise Ru complexes having different ligands;
a second electrode facing the porous layer on the first electrode; and
an electrolyte impregnated between the first and second electrodes.

12. A method of fabricating a dye-sensitized solar cell comprising:
preparing first and second electrodes, each electrode comprising a light transmission material;
forming a porous layer on a surface of the first electrode;
preparing a composite dye comprising two or more dye materials;
absorbing the composite dye to the porous layer;
positioning the second electrode facing the porous layer on the first electrode;
impregnating an electrolyte between the first and second electrodes; and
attaching the first and second electrodes to each other.

13. The method of claim 12, wherein the preparing a composite dye step comprises adding Ru(2,2′:6′-2″-terpyridine-4,4′,4″-tricarboxylic acid)(NCS)₃ to a dye precursor, wherein the Ru(2,2′:6′-2″-terpyridine-4,4′,4″-tricarboxylic acid)(NCS)₃ is present in the composite dye in an amount ranging from about 10 to about 80 mol %.

14. The method of claim 13, wherein the preparing a composite dye step comprises dissolving Ru(2,2′:6′-2″-terpyridine-4,4′,4″-tricarboxylic acid)(NCS)₃ in alcohol to a concentration ranging from about 0.1 to about 5 mM, and then adding a different dye material to the alcohol.

15. The method of claim 12, wherein composite dye comprises Ru(2,2′:6′-2″-terpyridine-4,4′,4″-tricarboxylic acid)(NCS)₃ and Ru(4,4′-dicarboxy-2,2′-bipyridine)₂(CN)₂.

16. The dye-sensitized solar cell according to claim 1, wherein the dye materials of the composite dye comprise:
a metal complex selected from the group consisting of Al complexes, Pt complexes, Pd complexes, Eu complexes, Pb complexes, Ir complexes, and Ru complexes.

17. The dye-sensitized solar cell according to claim 1, wherein the dye materials of the composite dye comprises an organic pigment.

18. The dye-sensitized solar cell according to claim 17, wherein the organic pigment is selected from the group consisting of coumarin, porphyrin, xanthene, riboflavin and triphenylmethane.

19. The dye-sensitized solar cell according to claim 5, wherein the porous layer further comprises a polymer.

20. The dye-sensitized solar cell according to claim 19, wherein the polymer is selected from the group consisting of polyethylene glycol, polyethylene oxide, polyvinyl alcohol and polyvinyl pyrrolidone.
